(19) United States
(12) Patent Application Publication
(10) Pub. No.: US 2026/0286523 A1
(43) Pub. Date: Sep. 24, 2026

(54) LOW-TEMPERATURE DEPOSITION MATERIAL, METHOD OF FORMING LOW-TEMPERATURE DEPOSITION FILM, AND SEMICONDUCTOR SUBSTRATE AND SEMICONDUCTOR DEVICE FABRICATED USING THE SAME

(71) Applicant: SOULBRAIN CO., LTD., Gyeonggi-do (KR)

(72) Inventors: Chang Bong YEON, Gyeonggi-do (KR); Jae Sun JUNG, Gyeonggi-do (KR)

(21) Appl. No.: 19/168,949

(22) PCT Filed: Mar. 29, 2024
(86) PCT No.: PCT/KR2024/004062

§ 371 Date: Sep. 25, 2025

(30) Foreign Application Priority Data
Mar. 30, 2023 (KR) 10-2023-0041817
Jan. 9, 2024 (KR) 10-2024-0003483
Mar. 29, 2024 (KR) 10-2024-0043068

(51) Int. Cl. C23C 16/455; C09D 1/00; C23C 16/18; C23C 16/34; C23C 16/44; H10W 20/00

(52) U.S. Cl. CPC C23C 16/45553; C09D 1/00; C23C 16/18; C23C 16/34; C23C 16/4408; H10W 20/032

(57) ABSTRACT

The present invention relates to a low-temperature deposition material, a method of forming a low-temperature deposition film, and a semiconductor substrate and semiconductor device fabricated using the same. According to the present invention, by applying a predetermined substance that is capable of acting as a strong reducing agent even in low-temperature processes, a low-resistance thin film and/or a metal nitride film may be effectively manufactured in a low-temperature process. In addition, film impurities due to ligands such as carbon may be reduced, and resistivity and physical properties such as crystallinity may be improved.

### TECHNICAL FIELD

The present invention relates to a low-temperature deposition material, a method of forming a low-temperature deposition film, and a semiconductor substrate and semiconductor device fabricated using the same. More particularly, according to the present invention, by applying a predetermined substance that is capable of acting as a strong reducing agent even in low-temperature processes, a low-resistance deposition film may be effectively manufactured in a low-temperature process. In addition, impurities in a deposition film caused by ligands such as carbon may be reduced, and physical properties such as roughness and crystallinity may be improved.

### BACKGROUND ART

As the advancement of performance and high integration of semiconductor devices are required, electrode materials or diffusion barrier materials with reduced resistivity are demanded.

These materials are provided in the form of a metal film and/or a metal nitride film through an atomic layer deposition (ALD) process. At this time, the reduction process requires the use of an extremely strong reducing agent or high heat energy.

However, the binding energy of H₂ used for the deposition is 467.7 kJ/mol, which requires high thermal energy during reduction. When high thermal energy is applied, the precursor compound is thermally decomposed, which may deteriorate step coverage or cause voids or seams on highly integrated or complex substrates with high aspect ratios.

In addition, impurities (C, Cl⁻, F⁻, etc.) in the low-temperature deposition film derived from the ligands of the precursor compound are introduced into the metal film and/or metal nitride film, causing contamination and disrupting the crystal arrangement, thereby reducing the density of the formed film and hindering electrical conductivity due to the low density.

Therefore, there is a need to develop a low-temperature deposition material that can form a uniform metal film and/or metal nitride film of a complex structure, has excellent physical properties such as crystallinity, and has low residual film impurities caused by ligands such as carbon, thereby providing a deposition film with low resistance even in a low-temperature process; a method of forming a low-temperature deposition film using the same; and a semiconductor substrate fabricated using the same.

### PATENT DOCUMENTS

KR 2019-0141071 A

### DISCLOSURE

### Technical Problem

Therefore, the present invention has been made in view of the above problems, and it is one object of the present invention to provide a method of forming a low-temperature deposition film and a semiconductor substrate fabricated using the same. According to the present invention, by applying a material with lower binding energy than H₂ as a low-temperature deposition material, impurity reduction, resistivity improvement, and improvement in deposition characteristics may be effectively achieved. Accordingly, even when forming a metal film on a substrate having a complex structure, a deposition film having a uniform thickness and low resistance even in a low-temperature process may be provided.

It is another object of the present invention to provide a method of performing a reduction reaction in a low-temperature process by applying a novel low-temperature deposition material.

It is yet another object of the present invention to provide a low-resistance deposition film while improving film quality such as electrical properties and density by applying a novel material that forms a metal film and/or a metal nitride film by performing a reduction reaction as a low-temperature deposition material.

The above and other objects can be accomplished by the present invention described below.

### Technical Solution

In accordance with one aspect of the present invention, provided is a low-temperature deposition material for a wiring metal, a metal having a melting point of 350° C. or less, or a wiring metal diffusion barrier, including one or more selected from a compound having a direct bond between hydrogen (H) and iodine, a compound having a direct bond between carbon (C) and iodine, and a compound having a direct bond between a halogen element (F, Cl, Br) and iodine.

The wiring metal or the metal having a melting point of 350° C. or less may be selected from Mo, W, Ru, Cu, Rh, Pb, Cd, Sn, Bi, In, and Ga.

The wiring metal diffusion barrier may be selected from a transition metal nitride film of Ti, Ta, Ni, Mo, Nb, Zr, V, or W, or a combination of two or more metals.

The compound having a direct bond between hydrogen (H) and iodine may have a total bonding energy of 305 to 325 kJ/mol as calculated using a Gaussian 16 program (basis set of DFT-D3/B3LYP (iodine: LanL2DZ, carbon, hydrogen elements: 6-31+G(d·p)).

The compound having a direct bond between carbon (C) and iodine may have a total bonding energy of 165 to 242 kJ/mol as calculated using a Gaussian 16 program (basis set of DFT-D3/B3LYP (iodine: LanL2DZ, carbon, hydrogen elements: 6-31+G(d·p)).

The compound having a direct bond between a halogen element (F, Cl, Br) and iodine may have a total bonding energy of 50 to 160 kJ/mol as calculated using a Gaussian 16 program (basis set of DFT-D3/B3LYP (iodine: LanL2DZ, carbon, hydrogen elements: 6-31+G(d·p)).

The low-temperature deposition material may include one or more selected from compounds represented by Chemical Formulas 1-1 to 1-11 below.

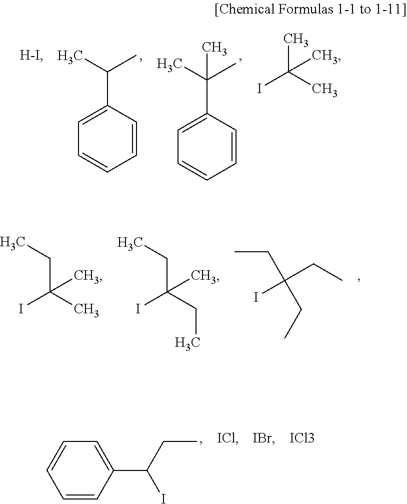

In accordance with another aspect of the present invention, provided is a method of forming a low-temperature deposition film, comprising depositing a deposition film using the low-temperature deposition material described above.

The deposition film may be a metal film and/or a metal nitride film.

The method of forming a low-temperature deposition film may include forming a deposition film through a reduction reaction while injecting a precursor compound and the low-temperature deposition material into a chamber and adsorbing the precursor compound and the low-temperature deposition material onto a surface of a substrate.

In the method of forming a low-temperature deposition film, a step of performing a reduction reaction by injecting hydrogen as a reactive gas may be omitted.

The method of forming a low-temperature deposition film may include a post-processing step of purging an inside of a chamber with a purge gas.

The chamber may be an ALD chamber, a CVD chamber, a PEALD chamber, or a PECVD chamber.

The low-temperature deposition film may be a laminated film of one or more selected from the group consisting of Mo, W, Ru, Cu, Rh, Pb, Cd, Sn, Bi, In, and Ga.

The metal nitride film may be a nitride film selected from a transition metal nitride film of Ti, Ta, Ni, Mo, Nb, Zr, V, or W, or a combination of two or more metals.

The low-temperature deposition film may be a wiring metal film, a wiring diffusion barrier, or a low-resistance metal film.

The wiring metal film may be a metal film of Mo, W, Ru, Cu, or Rh.

The wiring metal diffusion barrier may be a nitride film selected from a transition metal nitride film of Ti, Ta, Ni, Mo, Nb, Zr, V, or W, or a combination of two or more metals.

The low-resistance metal film may be a metal film having a melting point of 350° C. or less.

The low-resistance metal film may be a metal film of Pb, Cd, Sn, Bi, In, or Ga.

The low-temperature deposition film may be provided as a precursor compound for low-resistance metal films.

The precursor compound for low-resistance metal films may be a molecule having at least one selected from the group consisting of Mo, W, Ru, Cu, Rh, Pb, Cd, Sn, Bi, In, Ti, Ta, Ni, Mo, Nb, Zr, V, and Ga as a central metal atom (M) and having one or more ligands selected from C, N, O, H, and X (halogen), and may be a compound having a bond dissociation energy of 350 kJ/mol or less between the central metal atom and the ligands to reduce the central metal atom at a low process temperature of 400° C. or lower, as calculated using a Gaussian 16 program (basis set of DFT-D3/B3LYP (central metal, iodine: LanL2DZ, C, N, O, H, X: 6-31+G(d·p)).

The precursor compound may be a compound having at least one selected from the group consisting of Mo, W, Ru, Cu, Rh, Pb, Cd, Sn, Bi, In, Ti, Ta, Ni, Mo, Nb, Zr, V, and Ga as a central metal atom (M) and having a vapor pressure of greater than 0.01 mTorr and 100 Torr or less at 25° C.

The substrate loaded into the chamber may be heated to 100 to 700° C.

In the present invention, reactive gases commonly used in this technical field, such as ammonia, hydrogen, and oxygen, may be omitted. In addition, the process of separately injecting reactive gas and performing reduction treatment may be omitted.

The low-temperature deposition film may be a metal film such as a molybdenum metal film, a tungsten metal film, a ruthenium metal film, a copper metal film, a rhodium metal film, a lead metal film, a cadmium metal film, a tin metal film, a bismuth metal film, an indium metal film, or a gallium metal film.

The low-temperature deposition film may be a titanium nitride film, a tantalum nitride film, a vanadium nitride film, a tungsten nitride film, a nickel nitride film, a zirconium nitride film, a molybdenum nitride film, or the like, and may be a metal nitride film in which two or more types are combined for the purpose of a diffusion barrier, such as a titanium niobium nitride film or a titanium nickel nitride film.

The metal film and/or metal nitride film is characterized by having low resistivity, with a resistivity of 5 μΩ·cm to 1000 μΩ·cm.

The metal film and/or metal nitride film is characterized by having a ligand-derived film impurity content of 1% or less caused by a ligand such as carbon, as measured by XPS or SIMS.

The metal film and/or metal nitride film is characterized by improved crystallinity as measured by XRD due to the effect of reducing impurities within the film through stronger reduction of the metal precursor.

In accordance with still another aspect of the present invention, provided is a semiconductor substrate fabricated using the method of forming a low-temperature deposition film described above.

The low-temperature deposition film may be a metal film and/or a metal nitride film.

The low-temperature deposition film may have a multi-layer structure with 2 or 3 layers.

In accordance with yet another aspect of the present invention, provided is a semiconductor device including the semiconductor substrate described above.

### Advantageous Effects

According to the present invention, the present invention has an effect of providing a method of forming a metal film and/or metal nitride film. According to the method of the present invention, by applying a predetermined substance that is capable of acting as a strong reducing agent even in low-temperature processes, a reduction reaction (reduction of activation energy for reaction with reactive gas) can be provided at a process temperature where a precursor is not thermally decomposed. Accordingly, even when forming a metal film and/or metal nitride film on a substrate having a highly integrated or complex structure, a uniform metal film and/or metal nitride film can be formed.

In addition, when forming a metal film and/or metal nitride film, impurities and process byproducts of the metal film and/or metal nitride film caused by ligands such as carbon, which cause deterioration of film properties such as crystallinity and electrical properties, can be more effectively reduced, and the film quality can be improved. Thus, the crystallinity and resistivity of the metal film and/or metal nitride film can be improved, thereby improving the electrical properties thereof.

In addition, by reducing impurities and improving film quality, the present invention has an effect of providing a method of forming a high-quality low-temperature deposition film and a semiconductor substrate fabricated using the same.

### DESCRIPTION OF DRAWINGS

FIG. 1 includes graphs showing the AES analysis results for Example 5 according to the present invention at different temperatures.

FIG. 2 includes graphs showing the XRD analysis results for Example 5 according to the present invention and conventional Comparative Example 3 at different process temperatures.

FIG. 3 includes graphs showing the XRD analysis results for Example 6 according to the present invention and conventional Comparative Example 4.

FIGS. 4 and 5 are diagrams showing the reaction activation energies required to reduce the CO ligand of the Mo(CO)₆ precursor and the NO ligand of the (EtCp)Mo(CO)₂(NO) precursor in Example 8 and Comparative Example 5, respectively, in terms of H₂ and HI.

### BEST MODE

Hereinafter, a method of forming a low-temperature deposition film according to the present invention and a semiconductor substrate fabricated using the same will be described in detail.

In the present disclosure, the term “low-temperature deposition material” refers to a novel material capable of forming a metal film and/or metal nitride film through deposition by a reduction reaction in a low-temperature process, for example, at 600° C. or lower, preferably 550° C. or lower, more preferably 500° C. or lower.

In the present disclosure, the term “reduction reaction” refers to a reaction that not only replaces the ligand of a precursor compound but also reduces to the extent that a reduction reaction provided using a conventional reactive gas is omitted, unless otherwise specified.

In the present disclosure, the term “modification” means, unless otherwise specified, the positive interaction of a substance other than precursors and reactants with the reaction surface to improve film quality, such as reducing resistivity, increasing density, or reducing impurity of the deposition film.

In the present disclosure, unless otherwise stated, % refers to % by weight.

The present inventors confirmed that, when a predetermined low-temperature deposition material capable of performing a reduction reaction was used for a precursor compound adsorbed on the surface of a substrate loaded inside a chamber at a relatively low process temperature so that a precursor does not decompose, film quality such as electrical properties and crystallinity was improved while preventing the inflow of film impurities caused by ligands such as carbon. Based on these results, further related research was conducted and the present invention was completed.

For example, the low-temperature deposition film may provide a metal film by being provided with one or more precursors selected from the group consisting of Mo, W, Ru, Cu, Rh, Pb, Cd, Sn, Bi, In and Ga. In this case, the effects sought to be achieved in the present invention may be sufficiently achieved.

For example, the wiring metal diffusion barrier may be provided with one or more precursors selected from the group consisting of Ti, Ta, Ni, Mo, Nb, Zr, V, and W, and may provide a metal nitride film. In this case, the effects sought to be achieved in the present invention may be sufficiently achieved.

As a specific example, the low-temperature deposition film may have a film composition such as a molybdenum metal film, a tungsten metal film, a ruthenium metal film, a copper metal film, a rhodium metal film, a lead metal film, a cadmium metal film, a tin metal film, a bismuth metal film, an indium metal film, or a gallium metal film.

The low-temperature deposition film may include the aforementioned film composition alone or in a selective area, but is not limited thereto, and may also include SiH, SiOH, and the like.

The low-temperature deposition film may be a laminated film formed of one or more selected from the group consisting of Mo, W, Ru, Cu, Rh, Pb, Cd, Sn, Bi, In, and Ga.

The metal nitride film may be a laminated film formed of one or more selected from the group consisting of Ti, Ta, Ni, Mo, Nb, Zr, V, and W.

The low-temperature deposition film may be used in semiconductor devices as a general wiring metal film or low-resistance metal film.

The metal nitride film may be used in semiconductor devices as a general wiring metal diffusion barrier or low-resistance diffusion barrier.

The metal film and/or metal nitride film may have a resistivity of 5 μΩ·cm to 1000 μΩ·cm.

The wiring metal film may be a metal film formed of Mo, W, Ru, Cu, or Rh.

The low-resistance metal film may be a metal film having a melting point of 350° C. or less.

The low-resistance metal film may be a metal film formed of Pb, Cd, Sn, Bi, In, or Ga.

The low-temperature deposition film may be provided with a precursor compound for low-resistance metal films.

For example, the precursor compound may have a structure in which Mo, W, Ru, Cu, Rh, Pb, Cd, Sn, Bi, In, Ti, Ta, Ni, Mo, Nb, Zr, V, and Ga are a central metal atom (M) and ligands (L1, L2, L3, L4, L5, L6, and the like) are boned.

As a specific example, the precursor compound may be a molecule having Mo, W, Ru, Cu, Rh, Pb, Cd, Sn, Bi, In, Ti, Ta, Ni, Mo, Nb, Zr, V, or Ga as a central metal atom (M) and having one or more ligands selected from C, N, O, H, and X (halogen). When a precursor having a vapor pressure of 0.01 mTorr to 100 Torr at 25° C. is used, the effect of using the low-temperature deposition material may be maximized.

As another specific example, the precursor compound may be a molecule having at least one selected from the group consisting of Mo, W, Ru, Cu, Rh, Pb, Cd, Sn, Bi, In, Ti, Ta, Ni, Mo, Nb, Zr, V, and Ga as a central metal atom (M) and having one or more ligands selected from C, N, O, H, and X (halogen), and may be a compound having a bond dissociation energy of 350 kJ/mol or less between the central metal atom and the ligands to reduce the central metal atom at a low process temperature of 400° C. or lower, as calculated using a Gaussian 16 program (basis set of DFT-D3/B3LYP (central metal, iodine: LanL2DZ, C, N, O, H, X: 6-31+G(d·p)).

For example, when the central metal is divalent, L1 and L2 may be attached to the central metal as ligands. When the central metal is hexavalent, L1, L2, L3, L4, L5, and L6 may be attached to the central metal. The ligands corresponding to L1 to L6 may be the same or different.

For example, L1, L2, L3, L4, L5, and L6 may be the same or different as —H or —R. Here, —R may be a C1-C10 alkyl, a C1-C10 alkene, or a C1-C10 alkane, and may be linear or cyclic, and depending on the oxidation state of the central metal, the number n of L in L1, L2, L3, and L4 may be from 2 to 6.

For example, when the central metal is divalent, L1 and L2 may be attached to the central metal as ligands. When the central metal is hexavalent, L1, L2, L3, L4, L5, and L6 may be attached to the central metal. The ligands corresponding to L1 to L6 may be the same or different.

As a specific example, L1, L2, L3, L4, L5, and L6 may be the same or different as —H, —OR, or —NR₂. Here, —R may be H, a C1-C10 alkyl, a C1-C10 alkene, a C1-C10 alkane, iPr, or tBu. In this case, an appropriate reaction energy to be substituted by a reaction gas described later may be obtained.

As a specific example, L1, L2, L3, L4, L5, and L6 may be the same or different as —H or —X. Here, —X may be F, Cl, Br, or I. In this case, an appropriate reaction energy to be substituted by a reaction gas described later may be obtained.

As a specific example, L1, L2, L3, L4, L5, and L6 may be the same or different as —H or —R, Here, —R may be a C1-C10 alkyl, a C1-C10 alkene, or a C1-C10 alkane, and may have a linear or cyclic structure. In this case, an appropriate reaction energy to be substituted by a reaction gas described later may be obtained.

As a specific example, L1, L2, L3, L4, L5, and L6 may be the same or different as —H, —OR, or —NR₂. Here, —R may be H, a C1-C10 alkyl, a C1-C10 alkene, a C1-C10 alkane, iPr, or tBu. In this case, an appropriate reaction energy to be substituted by a reaction gas described later may be obtained.

As a specific example, L1, L2, L3, L4, L5, and L6 may be the same or different as —H or —X. Here, —X may be F, Cl, Br, or I. In this case, an appropriate reaction energy to be substituted by a reaction gas described later may be obtained.

For example, the precursor compound having molybdenum (Mo) as a central metal may be at least one selected from compounds having a structure represented by Chemical Formulas 2 and 3, and may include a trimethylene methane ligand and a derivative thereof, without being limited thereto.

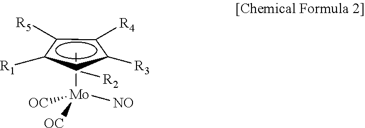

(In Chemical Formula 2, R1 to R5 are independently selected from hydrogen, an amino group, a silyl group, a C1-C8 alkyl group, and a C6-C8 aryl group, and the case where R1 to R5 are all hydrogen at the same time is excluded.)

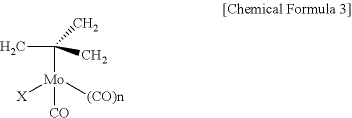

(In Chemical Formula 3, X includes H; F; Cl; Br; I; NO; CN; amidinate; guanidinate; ethylenediamine; propylenediamine; —NR6R7; —OR8; R9Cp; and a linear, branched, or cyclic, saturated or unsaturated hydrocarbon substituted with one or more of carbon (C), nitrogen (N), oxygen (O), phosphorus (P), and sulfur (S), R6, R7, R8, and R9 are independently selected from hydrogen, a C1-C12 alkyl group, and a C6-C12 aryl group, and n is an integer of 0 to 2.)

For example, the derivative of the trimethylene methane ligand may include a structure having a tribenzylidene methane ligand, a dibenzylidene methane ligand, and the like.

For example, the precursor compound having molybdenum (Mo) as a central metal may include Mo(CO)₆, (ethylbenzene)₂Mo, (2,6-diisopropylaniline)Mo(CO)₃, (1,4-diisopropyl-1,4-diazabutadiene)Mo(CO), Mo(CO) SPCl₂Me, molybdenum acetate dimer, (ethylbenzene)Mo(allyl)₂, MeCpMo(CO)₂(allyl), iprCpMo(CO)₂(allyl), Mo(thd)₃, (MeCp)Mo(EMA)₃, (tert-butylimido)Mo (MeCp)₂, TDMAMo, Cp2MoH2, Mo(dithiocabate)₄, (tert-butylimido)₂MoCl(aminothiolate), (tert-butylimido)₂Mo(tert-butylthiol) (aminothiolate), (tertbutylimido)₂Mo (aminothiolate)₂, (tert-butylimido)₂Mo(tert-butylthiol)₂, (tert-butylimido)₂Mo(tert-butylamine)₂, (tert-butylimido)₂Mo(CpEMA), MoO₂(ipr-amidinate)₂, (tert-butylimido)₂Mo(ipr-amidinate)₂, (tert-butylimido)₂Mo(tert-butoxy)₂, (tert-butylimido)₂ Mo(N,N-dimethyldiethylene triamine), (tert-butylimido)₂ Mo (hydrazido)Cl, MoO₂ (Dithiocarbamate)₂, (1,4-ditert-butyl-1,4,diazabutadiene)Mo(tert-butylimido)₂, MoO₂Cl₂, and the like.

Here, MoO₂Cl₂, (ethylbenzene)₂Mo, (2,6-diisopropylaniline)Mo(CO)₃, (benzene)Mo(CO)₃, and 1,4-diisopropyl-1,4-diazabutaiene)Mo(CO)₃ may be compounds represented by Chemical Formulas 4-1 to 4-5, respectively.

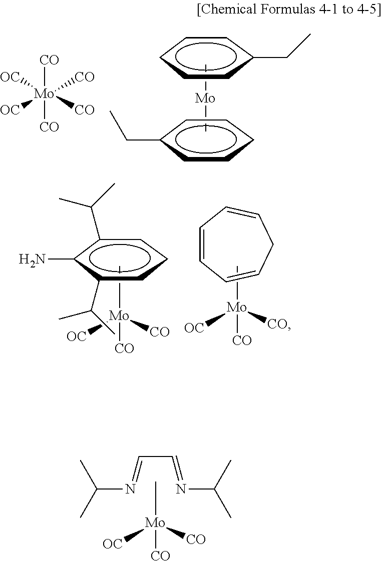

Here, the Mo(CO) SPCl₂Me, a molybdenum acetate dimer, (ethylbenzene)Mo(allyl)₂, and MeCpMo(CO)₂(allyl)′ ⁱprCpMo(CO)₂(allyl) may be compounds represented by Chemical Formulas 4-6 to 4-10 below, respectively.

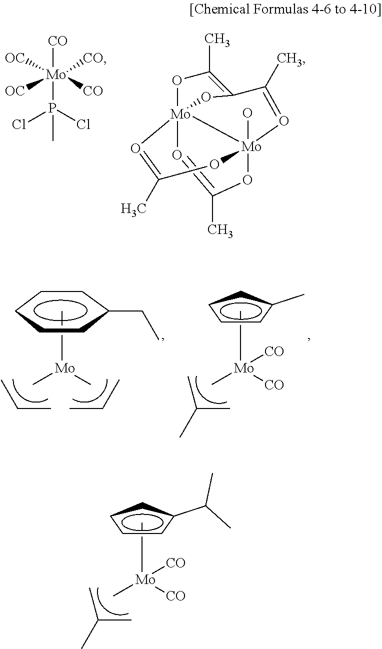

Here, Mo(thd)₃, (MeCp)Mo(EMA)₃, (tert-butylimido)Mo (MeCp)₂, TDMAMo, and Cp2MoH2 may be compounds represented by Chemical Formulas 4-11 to 4-15 below, respectively.

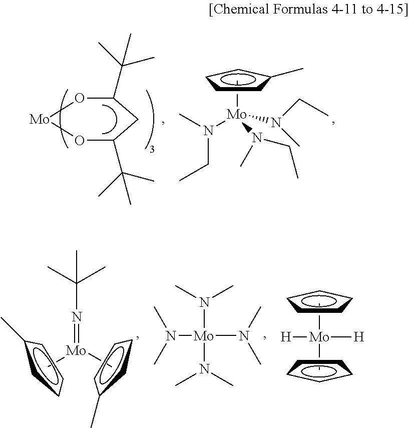

Here, Mo(dithiocabate)₄, (tert-butylimido)₂MoCl (aminothiolate), (tert-butylimido)₂Mo(tert-butylthiol)(aminothiolate), (tertbutylimido)₂Mo(aminothiolate)₂, and (tert-butylimido)₂Mo(tert-butylthiol)₂ may be compounds represented by Chemical Formulas 4-16 to 4-20 below, respectively.

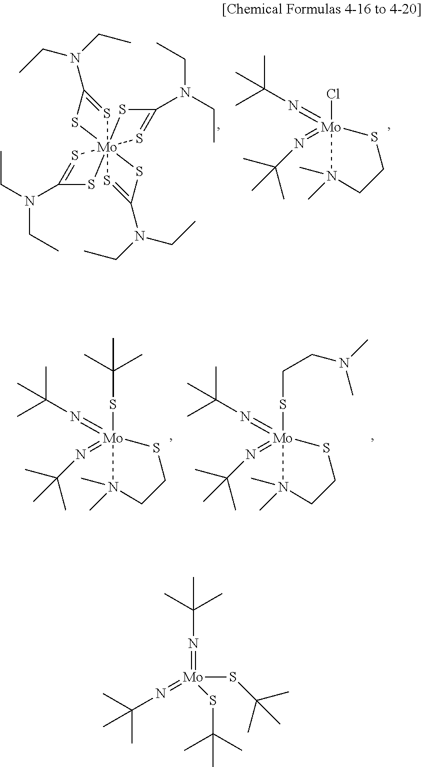

Here, (tert-butylimido)₂Mo(tert-butylamine)₂, (tert-butylimido)₂Mo(CpEMA), MoO₂ (ipr-amidinate)₂, and (tert-butylimido)₂Mo(ipr-amidinate)₂ may be compounds represented by Chemical Formulas 4-21 to 4-24 below, respectively.

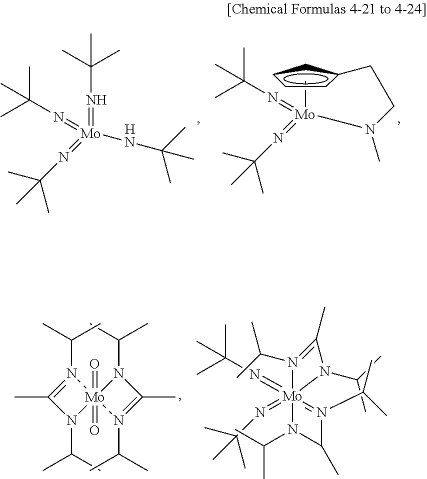

Here, (tert-butylimido)₂Mo(tert-butoxy)₂, (tert-butylimido)₂ Mo(N,N-dimethyldiethylene triamine), (tert-butylimido)₂ Mo(hydrazido)Cl, MoO₂ (dithiocarbamate)₂, 1,4-ditert-butyl-1,4,diazabutadiene)Mo(tert-butylimido)₂, MoO₂Cl₂ (tert-butylimido)₂Mo(dimethylamide)₂, and (methylbenzene)₂Mo may be compounds represented by Chemical Formulas 4-25 to 4-31 below, respectively.

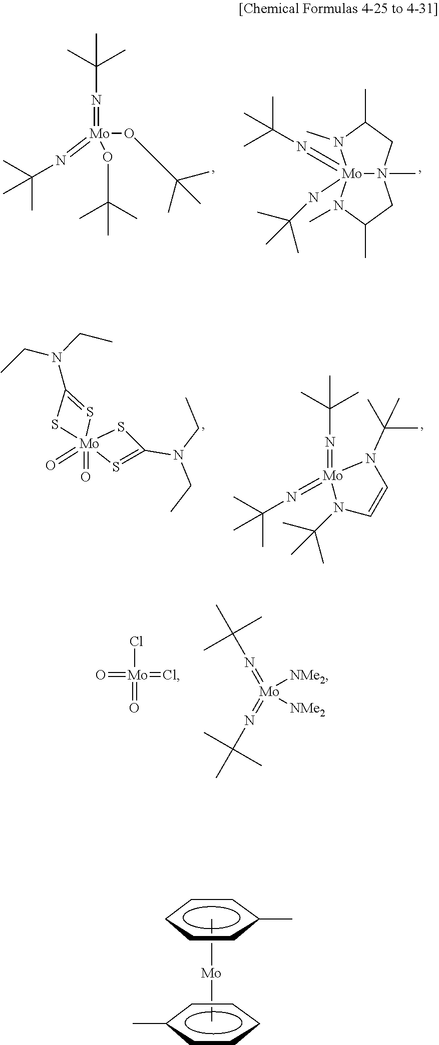

For example, the precursor compound may be mixed with a non-polar solvent and used. In this case, the viscosity or vapor pressure of the precursor compound may be easily controlled.

The low-temperature deposition material of the present invention may effectively replace ligands by reducing the activation energy of a precursor compound adsorbed on the substrate. In addition, the low-temperature deposition material has reducing power and performs a reduction reaction, thereby eliminating the reduction process using a reactive gas required in the process.

For example, the substitution for the ligands may be formed on the entire substrate or a portion of the substrate on which the low-temperature deposition film is formed.

For example, the low-temperature deposition material may include one or more selected from a compound having a direct bond between hydrogen (H) and iodine, a compound having a direct bond between carbon (C) and iodine, and a compound having a direct bond between a halogen element (F, Cl, Br) and iodine.

The low-temperature deposition material may form a film by performing a reduction reaction without a separate reaction gas such as H₂.

The compound having a direct bond between hydrogen (H) and iodine may have a total bonding energy of 305 to 325 kJ/mol as calculated using a Gaussian 16 program (basis set of DFT-D3/B3LYP (iodine: LanL2DZ, carbon, hydrogen elements: 6-31+G(d·p)). In this case, a low-resistance thin film may be effectively provided.

The compound having a direct bond between carbon (C) and iodine may have a total bonding energy of 165 to 242 kJ/mol as calculated using a Gaussian 16 program (basis set of DFT-D3/B3LYP (iodine: LanL2DZ, carbon, hydrogen elements: 6-31+G(d·p)). In this case, the content of film impurities caused by ligands such as carbon may be reduced, and a low-resistance thin film may be effectively provided.

The compound having a direct bond between a halogen element (F, Cl, Br) and iodine may have a total bonding energy of 50 to 160 kJ/mol as calculated using a Gaussian 16 program (basis set of DFT-D3/B3LYP (iodine: LanL2DZ, carbon, hydrogen elements: 6-31+G(d·p)). In this case, a low-resistance thin film may be effectively provided.

In the low-temperature deposition material, the compound having a direct bond between hydrogen (H) and iodine may have a total bonding energy of 305 to 325 kJ/mol as calculated using a Gaussian 16 program (basis set of DFT-D3/B3LYP (iodine: LanL2DZ, carbon, hydrogen elements: 6-31+G(d·p)). In this case, the content of film impurities caused by ligands such as carbon may be reduced, and a low-resistance thin film may be effectively provided.

The low-temperature deposition material may include one or more selected from compounds represented by Chemical Formulas 1-1 to 1-11 below.

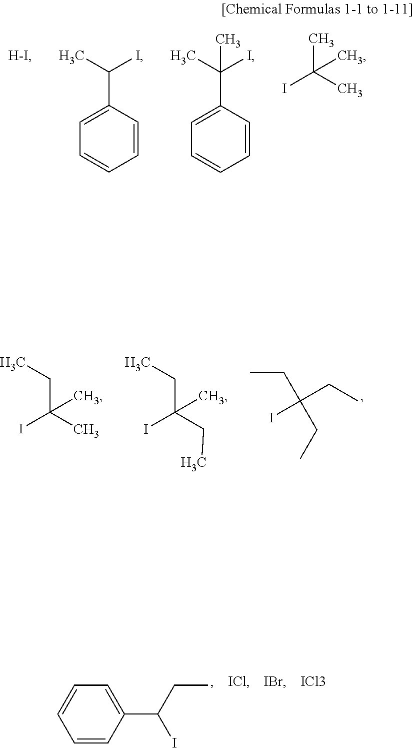

For example, the low-temperature deposition material is 3 N to 15 N hydrogen iodide, a gas mixture containing 1 to 99% by weight of 3 N to 15 N hydrogen iodide and a residual amount (amount that makes a total amount 100% by weight) of an inert gas, or an aqueous solution mixture containing 0.5 to 70% by weight of 3 N to 15 N hydrogen iodide and a residual amount (amount that makes a total amount 100% by weight) of water. Here, the inert gas may be nitrogen, helium, or argon with a purity of 4 N to 9 N. In this case, impurities may be reduced through the reduction reaction, and low-resistance thin films or metal nitride films may be effectively formed.

Preferably, the low-temperature deposition material is 5 N to 6 N hydrogen iodide, a gas mixture containing 1 to 99% by weight of 5 N to 6 N hydrogen iodide and a residual amount (amount that makes a total amount 100% by weight) of an inert gas, or an aqueous solution mixture containing 0.5 to 70% by weight of 5 N to 6 N hydrogen iodide and a residual amount (amount that makes a total amount 100% by weight) of water. Here, the inert gas may be nitrogen, helium, or argon having a purity of 4 N to 9 N. In this case, side reactions may be suppressed during the formation of a low-temperature deposition film, and thin film growth rate may be adjusted. Thus, process by-products in the low-temperature deposition film may be reduced, so that corrosion or deterioration may be decreased, and improvements in film quality, such as enhancement of the crystallinity of the thin film, may be achieved. In addition, even when forming a thin film on a substrate having a highly integrated or complex structure, the thickness uniformity of a thin film may be greatly improved.

In this case, by sufficiently providing a reduction effect to a precursor compound adsorbed on a substrate at a relatively low process temperature at which a precursor is not thermally decomposed, when a thin film is formed on a substrate having a highly integrated or complex structure, the thickness uniformity of a thin film may be greatly improved. In addition to the precursor, process by-products may be prevented from being adsorbed, thereby effectively protecting the surface of the substrate. In addition, the reaction rate may be reduced, and process by-products may be effectively removed.

The low-temperature deposition material may be preferably a compound having a purity of 99.9% or more, 99.95% or more, or 99.99% or more. For reference, when a compound having a purity of less than 99% is used, impurities may remain in a thin film or cause side reactions with precursors or reactants. Accordingly, it is desirable to use a material having a purity of 99% or more.

For example, the low-temperature deposition film may contain a halogen compound in an amount of 100 ppm or less. For reference, when halogen excessively remains, when a nitriding agent described later is used under a temperature condition of 200 to 300° C., a chloride such as NH₄Cl may be generated and remain in the low-temperature deposition film, which is undesirable.

The low-temperature deposition film may be used for purposes such as a wiring metal film or a low-resistance metal film, without being limited thereto.

In particular, as a relatively coarse thin film is formed, the growth rate of a thin film formed at the same time is greatly reduced, so that even when applied to a substrate having a complex structure, the uniformity of the thin film may be secured, and the thin film may be deposited in a thin thickness. In addition, the remaining amounts of O, Si, metals, and metal oxides remaining as process by-products may be improved. In addition, even the remaining amount of carbon, which was difficult to reduce in the past, may be improved.

The method of forming a low-temperature deposition film according to one embodiment of the present invention includes a step of forming a deposition film through a reduction reaction while injecting a precursor compound and the low-temperature deposition material into a chamber and adsorbing the precursor compound and the low-temperature deposition material onto the surface of a substrate. In this case, the reduction of the precursor adsorbed on a substrate may be effectively performed at a relatively low process temperature that prevents the precursor from thermally decomposing. Furthermore, by appropriately reducing the thin film growth rate, film uniformity may be significantly improved and a low-resistance deposition film may be provided, even when deposited on substrates with highly integrated or complex structures.

The low-temperature deposition material and precursor compound may be transferred into the chamber by a VFC method, a DLI method, or an LDS method.

The input amount (mg/cycle) ratio of the precursor compound to the low-temperature deposition material in the chamber may be 1:1 to 1:20.

In the step of injecting the low-temperature deposition material onto the surface of the substrate, the feeding time (sec) per cycle of the low-temperature deposition material onto the surface of the substrate may be preferably 0.01 to 10 seconds, more preferably 0.02 to 8 seconds, still more preferably 0.04 to 6 seconds, still more preferably 0.05 to 4 seconds. Within this range, the thin film growth rate may be reduced, and step coverage and cost efficiency may be excellent.

In the present disclosure, the feeding time of the low-temperature deposition material is based on a flow rate of 0.1 to 8,000 mg/cycle for a chamber volume of 15 to 20 L, more specifically, on a flow rate of 10 to 5,000 mg/cycle for a chamber volume of 18 L.

As a specific example, the method of forming a low-temperature deposition film may include a step of forming a deposition film through a reduction reaction while injecting a precursor compound and the low-temperature deposition material into a chamber and adsorbing the precursor compound and the low-temperature deposition material onto the surface of a substrate; and a step of purging the inside of the chamber with a purge gas.

The entire steps described above may be defined as a unit cycle, and the cycle may be repeatedly performed until a low-temperature deposition film having a desired thickness is obtained. In this way, when the low-temperature deposition material and the precursor compound are simultaneously introduced within one cycle to improve the film quality, the generated process by-products may be effectively removed, thereby reducing the resistivity, greatly improving step coverage, and enhancing the uniformity. Thus, a low-resistance deposition film having improved film quality such as electrical properties, dielectric properties, and density may be provided.

The chamber may be an ALD chamber, a CVD chamber, a PEALD chamber, or a PECVD chamber.

The substrate loaded into the chamber may be heated to 100 to 700° C.

The low-temperature deposition material or precursor compound may be vaporized and injected, followed by plasma post-processing. In this case, the thin film growth rate may be improved, and process byproducts may be reduced.

In the purging step, the amount of purge gas injected into the ALD chamber is not particularly limited as long as the amount is sufficient to remove the unadsorbed precursor compound. For example, the amount may be 10 to 10,000 times, preferably 50 to 50,000 times, more preferably 100 to 10,000 times the volume of the precursor compound injected into the chamber. Within this range, by sufficiently removing the unadsorbed precursor compound, a thin film may be formed evenly and deterioration of film quality may be prevented. Here, the input amounts of the purge gas and precursor compound are each based on one cycle, and the volume of the precursor compound refers to the volume of the vaporized precursor compound vapor.

The low-temperature deposition material and the precursor compound may preferably be transferred into the ALD chamber by a VFC method, a DLI method, or an LDS method, and more preferably, by a VFC method.

For example, the substrate loaded into the chamber may be heated to 100 to 700° C., as a specific example, 300 to 600° C. The low-temperature deposition material or precursor compound may be injected onto the substrate in an unheated or heated state, or may be injected unheated and then heated during the deposition process, depending on the deposition efficiency. For example, the low-temperature deposition material or precursor compound may be injected onto the substrate at 50 to 400° C. for 1 to 20 seconds.

The input amount (mg/cycle) ratio of the precursor compound to the low-temperature deposition material in the chamber may be preferably 1:1 to 1:400, more preferably 1:2 to 1:350, still more preferably 1:2 to 1:300, still more preferably 1:2.5 to 1:200. Within this range, step coverage may be improved, and process by-products may be greatly reduced.

For example, the method of forming a low-temperature deposition film may be performed at a deposition temperature of 100 to 600° C., preferably 300 to 500° C., more preferably 300 to 400° C. Within this range, a deposition film with excellent film quality may be grown while implementing ALD process characteristics.

For example, the method of forming a low-temperature deposition film may be performed under a deposition pressure of 0.01 to 20 Torr, preferably 0.1 to 20, more preferably 0.1 to 10 Torr, most preferably 0.3 to 7 Torr. Within this range, a low-temperature deposition film having a uniform thickness may be obtained.

In the present disclosure, the deposition temperature and the deposition pressure may be measured as temperature and pressure formed within the deposition chamber, or as temperature and pressure applied to the substrate within the deposition chamber.

The method of forming a low-temperature deposition film may preferably include a step of increasing the temperature inside the chamber to a deposition temperature before introducing the precursor compound into the chamber; and/or a step of performing purging by injecting an inert gas into the chamber before introducing the precursor compound into the chamber.

In the method of forming a low-temperature deposition film, the intensity (c/s) of residual impurities (carbon or halogen element) in the low-temperature deposition film may be preferably 100,000 or less, more preferably 70,000 or less, still more preferably 50,000 or less, still more preferably 10,000 or less, as a preferred example, 5,000 or less, still more preferably 10 to 4,000, still more preferably 10 to 3,000 as measured using a low-temperature deposition film having a thickness of 100 Å according to SIMS. Within this range, crystallinity may be excellent, and deterioration of electrical properties may be prevented.

In the present disclosure, purging may be performed at preferably 1,000 to 50,000 sccm (standard cubic centimeter per minute), more preferably 2,000 to 30,000 sccm, still more preferably 2,500 to 15,000 sccm. Within this range, the thin film growth rate per cycle may be appropriately controlled. In addition, since deposition is performed as an atomic mono-layer or nearly an atomic mono-layer, the film quality may be improved.

In addition, as a manufacturing device capable of implementing the low-temperature deposition film manufacturing method, the present invention may include a manufacturing device including an ALD chamber, a first vaporizer for vaporizing a precursor compound, a first transport means for transporting the vaporized precursor compound into the ALD chamber, a second vaporizer for vaporizing a low-temperature deposition material, and a second transport means for transporting the vaporized low-temperature deposition material into the ALD chamber. Here, vaporizers and transport means commonly used in the technical field to which the present invention pertains may be used in the present invention without particular limitation.

As a specific example, the method of forming a low-temperature deposition film is explained. First, a substrate on which a deposition film is to be formed is placed in a deposition chamber capable of atomic layer deposition.

The substrate may include a semiconductor substrate, such as a silicon substrate or a silicon oxide substrate.

The substrate may further have a conductive layer or an insulating layer formed on the upper portion thereof.

To deposit a deposition film on the substrate placed in the deposition chamber, the above-described low-temperature deposition material, the precursor compound, or a mixture of the low-temperature deposition material and the non-polar solvent are each prepared.

Next, the prepared low-temperature deposition material, the precursor compound, or a mixture of the prepared low-temperature deposition material and a non-polar solvent (hereinafter referred to as composition for forming a deposition film) is injected into the vaporizer, is transformed into a vapor phase, is transferred into the deposition chamber, and is adsorbed on the substrate. Then, the unadsorbed material or a mixture of the unadsorbed material and a non-polar solvent is purged.

The non-polar solvent may preferably include one or more selected from the group consisting of alkanes and cycloalkanes. In this case, an organic solvent with low reactivity and solubility and easy moisture management may be included. In addition, step coverage may be improved even when deposition temperature increases during the formation of a low-temperature deposition film.

As a preferred example, the non-polar solvent may include a C1 to C10 alkane or a C3 to C10 cycloalkane, preferably a C3 to C10 cycloalkane. In this case, reactivity and solubility may be low and moisture management may be easy.

In the present disclosure, C1, C3, and the like indicate the number of carbon atoms.

The cycloalkane may preferably include C3 to C10 monocycloalkanes, and among the monocycloalkanes, cyclopentane is liquid at room temperature and has the highest vapor pressure, so cyclopentane is preferable in the vapor deposition process, but the present invention is not limited thereto.

For example, the non-polar solvent may have a solubility (25° C.) of 200 mg/L or less, preferably 50 to 400 mg/L, more preferably 135 to 175 mg/L in water. Within this range, the reactivity toward the precursor compound may be reduced, and moisture may be easily managed.

In the present disclosure, solubility may be measured without any particular limitation by a measurement method or standard commonly used in the technical field to which the present invention pertains. For example, solubility may be measured by the HPLC method using a saturated solution.

Based on a total weight of the precursor compound and the non-polar solvent, the non-polar solvent may be included in an amount of 5 to 95% by weight, more preferably 10 to 90% by weight, still more preferably 40 to 90% by weight, most preferably 70 to 90% by weight.

When the content of the non-polar solvent exceeds the above range, impurities may be generated, which may increase the resistance and impurities within a thin film. When the content of the organic solvent is less than the range, the effect of improving step coverage due to solvent addition and the effect of reducing impurities such as chloride (Cl) ions may be reduced.

For example, in the method of forming a low-temperature deposition film, a step of injecting the precursor compound and the low-temperature deposition material into the chamber to adsorb the precursor compound and the low-temperature deposition material on the substrate surface and a step of purging the unadsorbed material may be set as a unit cycle, and the unit cycle may be repeated to form a low-temperature deposition film having a desired thickness.

For example, the unit cycle may be repeated 1 to 99,999 times, preferably 10 to 1,000 times, more preferably 50 to 5,000 times, still more preferably 100 to 2,000 times. Within this range, the desired thin film properties may be well expressed.

In addition, the present invention provides a semiconductor substrate, and the semiconductor substrate is fabricated by the method of forming a low-temperature deposition film of the present invention. In this case, the thickness uniformity of a thin film may be excellent, and the density and electrical properties thereof may be excellent.

Preferably, the low-temperature deposition film has a thickness of 30 nm or less, a resistivity value of 5 to 2,000 μΩ·cm based on a thickness of 10 nm of the low-temperature deposition film, an impurity content of 10,000 ppm or less, and a step coverage of 90% or more. Within this range, the low-temperature deposition film performs well as a diffusion barrier and is effective as a metal wiring material, without being limited thereto.

For example, the low-temperature deposition film may have a thickness of 0.1 to 30 nm, preferably 1 to 20 nm, more preferably 2 to 10 nm. Within this range, excellent thin film properties may be realized.

For example, based on a thickness of 10 nm of the low-temperature deposition film, the low-temperature deposition film may have a resistivity value of 0.1 to 400 μΩ·cm, preferably 0.1 to 200 μΩ·cm, more preferably 0.1 to 20 μΩ·cm. Within this range, excellent thin film properties may be realized.

The low-temperature deposition film may have an impurity content of preferably 10,000 ppm or less or 1 to 9,000 ppm, still more preferably 1 to 8,500 ppm, still more preferably 1 to 1,000 ppm. Within this range, the crystallinity of the thin film may be excellent, and the resistivity can be improved. Here, the impurities remaining in the low-temperature deposition film are impurities resulting from insufficient reduction of the metal precursor ligand, and may include, for example, carbon, nitrogen, oxygen, or halogen elements. As the residual amount of impurities in the low-temperature deposition film decreases, film quality may be improved.

The low-temperature deposition film is characterized by having a ligand-derived film impurity content of less than 1%, including carbon impurities, as measured by XPS.

In the present disclosure, unless otherwise stated, % is based on weight.

For example, the low-temperature deposition film may have a step coverage of 90% or more, preferably 92% or more, more preferably 95% or more. Within this range, the thin film may be easily deposited on a substrate even with a complex structure, and thus may be applied to next-generation semiconductor devices.

The manufactured low-temperature deposition film may preferably have a thickness of 20 nm or less, a impurity content, such as carbon, nitrogen, oxygen, and halogens, of 10,000 ppm or less based on a thickness of 10 nm of the low-temperature deposition film, and a step coverage of 90% or more. Within this range, excellent performance effects may be achieved as a dielectric film or blocking film, without being limited thereto.

The low-temperature deposition film is characterized by improved crystallinity as measured by XRD.

The low-temperature deposition film is characterized by improved resistivity.

Hereinafter, preferred examples and drawings are presented to help understand the present invention, but the following examples and drawings are only illustrative of the present invention, and it is obvious to those skilled in the art that various changes and modifications are possible within the scope and technical idea of the present invention. Such changes and modifications fall within the scope of the appended patent claims.

### EXAMPLES

### Example 1

An ALD deposition process was performed using 5 N HI as a low-temperature deposition material and a BTBMMo precursor represented by the chemical formula below as a precursor compound.

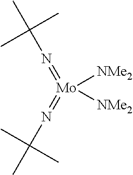

First, the prepared precursor compound was placed in a separate canister and supplied to a separate vaporizer heated to 150° C. at a flow rate of 0.1 g/min using a liquid mass flow controller (LMFC) at room temperature. Then, the BTBMMo precursor vaporized in a vapor phase in the vaporizer was injected into the deposition chamber for 3 seconds, and then argon gas was supplied at 5000 sccm for 10 seconds to perform argon purging. At this time, the pressure inside the reaction chamber was controlled to 2.5 Torr.

Next, the prepared low-temperature deposition material was placed in the canister and supplied to the chamber at a flow rate of 1000 sccm using a mass flow controller (MFC) at room temperature. Then, the low-temperature deposition material vaporized in a vapor phase in the vaporizer was injected into the substrate-loaded deposition chamber for 2 seconds to perform a reduction reaction, and then argon gas was supplied at 5000 sccm for 10 seconds to perform argon purging. At this time, the pressure inside the reaction chamber was controlled to 2.5 Torr. This process was repeated 200 to 400 times while maintaining the deposition temperature at 350° C. to form a self-limiting atomic layer metal film with a thickness of 10 nm.

Using an ellipsometer which is a device capable of measuring optical properties such as thickness and refractive index of the metal film by using the polarization characteristics of light for the manufactured low-temperature deposition film (MoN metal film), the thickness of the metal film deposited per cycle was calculated by dividing the measured thickness of the metal film by the number of cycles, and the result was 10 nm. The component analysis of the metal film was performed through AES and SIMS analyses. Then, sheet resistance was measured using the four-probe measurement method, and the resistivity value was calculated by using the measured thickness.

### Example 2

An ALD deposition process was performed using 5 N HI as a low-temperature deposition material, NH₃ as a reactive gas, and a BTBMMo precursor represented by the chemical formula below as a precursor compound.

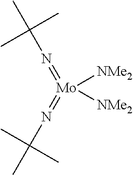

First, the prepared precursor compound was placed in a separate canister and supplied to a separate vaporizer heated to 150° C. at a flow rate of 0.1 g/min using a liquid mass flow controller (LMFC) at room temperature. Then, the BTBMMo precursor vaporized in a vapor phase in the vaporizer was injected into the deposition chamber for 3 seconds, and then argon gas was supplied at 5000 sccm for 10 seconds to perform argon purging. At this time, the pressure inside the reaction chamber was controlled to 2.5 Torr.

Next, the prepared HI low-temperature deposition material was placed in the canister and supplied to the chamber at a flow rate of 1000 sccm using a mass flow controller (MFC) at room temperature. Then, the low-temperature deposition material vaporized in a vapor phase in the vaporizer was injected into the substrate-loaded deposition chamber for 2 seconds to perform a catalytic reaction, and then argon gas was supplied at 5000 sccm for 10 seconds to perform argon purging. Then, after supplying NH₃ as a reducing agent into the chamber at a flow rate of 1000 sccm, argon gas was supplied at 5000 sccm for 10 seconds to perform argon purging. At this time, the pressure inside the reaction chamber was controlled to 2.5 Torr. This process was repeated 200 to 400 times while maintaining the deposition temperature at 350° C. to form a self-limiting atomic layer metal film with a thickness of 10 nm.

Using an ellipsometer which is a device capable of measuring optical properties such as thickness and refractive index of the metal film by using the polarization characteristics of light for the manufactured low-temperature deposition film (MoN metal film), the thickness of the metal film deposited per cycle was calculated by dividing the measured thickness of the metal film by the number of cycles, and the result was 10 nm. The component analysis of the metal film was performed through AES and SIMS analyses. Then, sheet resistance was measured using the four-probe measurement method, and the resistivity value was calculated by using the measured thickness.

### Example 3

An ALD deposition process was performed using 5 N HI as a low-temperature deposition material and a BTBTBMo precursor represented by the chemical formula below as a precursor compound.

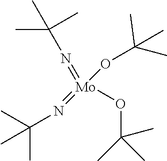

First, the prepared precursor compound was placed in a separate canister and supplied to a separate vaporizer heated to 150° C. at a flow rate of 0.1 g/min using a liquid mass flow controller (LMFC) at room temperature. Then, the BTBTBMo precursor vaporized in a vapor phase in the vaporizer was injected into the deposition chamber for 3 seconds, and then argon gas was supplied at 5000 sccm for 10 seconds to perform argon purging. At this time, the pressure inside the reaction chamber was controlled to 2.5 Torr.

Next, the prepared low-temperature deposition material was placed in the canister and supplied to the chamber at a flow rate of 1000 sccm using a mass flow controller (MFC) at room temperature. Then, the low-temperature deposition material vaporized in a vapor phase in the vaporizer was injected into the substrate-loaded deposition chamber for 2 seconds to perform a reduction reaction, and then argon gas was supplied at 5000 sccm for 10 seconds to perform argon purging. At this time, the pressure inside the reaction chamber was controlled to 2.5 Torr. This process was repeated 200 to 400 times while maintaining the deposition temperature at 350° C. to form a self-limiting atomic layer metal film with a thickness of 10 nm.

Using an ellipsometer which is a device capable of measuring optical properties such as thickness and refractive index of the metal film by using the polarization characteristics of light for the manufactured low-temperature deposition film (MoN metal film), the thickness of the metal film deposited per cycle was calculated by dividing the measured thickness of the metal film by the number of cycles, and the result was 10 nm. The component analysis of the metal film was performed through AES and SIMS analyses. Then, sheet resistance was measured using the four-probe measurement method, and the resistivity value was calculated by using the measured thickness.

### Example 4

An ALD deposition process was performed using 5 N HI as a low-temperature deposition material, NH₃ as a reactive gas, and a BTBTBMo precursor represented by the chemical formula below as a precursor compound.

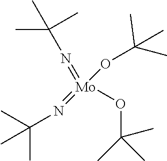

First, the prepared precursor compound was placed in a separate canister and supplied to a separate vaporizer heated to 150° C. at a flow rate of 0.1 g/min using a liquid mass flow controller (LMFC) at room temperature. Then, the BTBTBMo precursor vaporized in a vapor phase in the vaporizer was injected into the deposition chamber for 3 seconds, and then argon gas was supplied at 5000 sccm for 10 seconds to perform argon purging. At this time, the pressure inside the reaction chamber was controlled to 2.5 Torr.

Next, the prepared HI low-temperature deposition material was placed in the canister and supplied to the chamber at a flow rate of 1000 sccm using a mass flow controller (MFC) at room temperature. Then, the low-temperature deposition material vaporized in a vapor phase in the vaporizer was injected into the substrate-loaded deposition chamber for 2 seconds to perform a catalytic reaction, and then argon gas was supplied at 5000 sccm for 10 seconds to perform argon purging. Then, after supplying NH₃ as a reducing agent into the chamber at a flow rate of 1000 sccm, argon gas was supplied at 5000 sccm for 10 seconds to perform argon purging. At this time, the pressure inside the reaction chamber was controlled to 2.5 Torr. This process was repeated 200 to 400 times while maintaining the deposition temperature at 350° C. to form a self-limiting atomic layer metal film with a thickness of 10 nm.

Using an ellipsometer which is a device capable of measuring optical properties such as thickness and refractive index of the metal film by using the polarization characteristics of light for the manufactured low-temperature deposition film (MoN metal film), the thickness of the metal film deposited per cycle was calculated by dividing the measured thickness of the metal film by the number of cycles, and the result was 10 nm. Metal film component analysis was performed using AES and SIMS analysis. Then, sheet resistance was measured using the four-probe measurement method, and the resistivity value was calculated by using the measured thickness.

### Example 5

An ALD deposition process was performed using 5 N HI as a low-temperature deposition material and an Mo(CO)₆ precursor represented by the chemical formula below as a precursor.

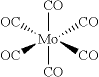

First, the prepared precursor compound was placed in a separate canister and heated to 50° C. Then, the Mo(CO)₆ precursor was injected into the deposition chamber with 50 sccm of Ar carrier for 3 seconds, and then argon gas was supplied at 5000 sccm for 10 seconds to perform argon purging. At this time, the pressure inside the reaction chamber was controlled to 2.5 Torr.

Next, the prepared low-temperature deposition material was placed in the canister and supplied to the chamber at a flow rate of 1000 sccm using a mass flow controller (MFC) at room temperature. Then, the low-temperature deposition material vaporized in a vapor phase in the vaporizer was injected into the substrate-loaded deposition chamber for 2 seconds to perform a reduction reaction, and then argon gas was supplied at 5000 sccm for 10 seconds to perform argon purging. At this time, the pressure inside the reaction chamber was controlled to 2.5 Torr. This process was repeated 50 to 200 times while maintaining the deposition temperature at 375° C. to form a self-limiting atomic layer metal film with a thickness of 10 nm.

Using an ellipsometer which is a device capable of measuring optical properties such as thickness and refractive index of the metal film by using the polarization characteristics of light for the manufactured low-temperature deposition film (Mo metal film), the thickness of the metal film deposited per cycle was calculated by dividing the measured thickness of the metal film by the number of cycles, and the result was 10 nm. Then, sheet resistance was measured using the four-probe measurement method, and the resistivity value was calculated by using the measured thickness. The crystallinity of the Mo metal film was confirmed through XRD analysis.

### Example 6

An ALD deposition process was performed using 5 N HI as a low-temperature deposition material and an Mo(tol)₂ precursor represented by the chemical formula below as a precursor.

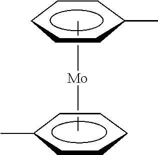

First, the prepared precursor compound was placed in a separate canister and heated to 130° C. Then, the Mo(tol)₂ precursor was injected into the deposition chamber with 50 sccm of Ar carrier for 10 seconds, and then argon gas was supplied at 5000 sccm for 10 seconds to perform argon purging. At this time, the pressure inside the reaction chamber was controlled to 2.5 Torr.

Next, the prepared low-temperature deposition material was placed in the canister and supplied to the chamber at a flow rate of 1000 sccm using a mass flow controller (MFC) at room temperature. Then, the low-temperature deposition material vaporized in a vapor phase in the vaporizer was injected into the substrate-loaded deposition chamber for 2 seconds to perform a reduction reaction, and then argon gas was supplied at 5000 sccm for 10 seconds to perform argon purging. At this time, the pressure inside the reaction chamber was controlled to 2.5 Torr. This process was repeated 30 to 300 times while maintaining the deposition temperature at 250° C. to form a self-limiting atomic layer metal film with a thickness of 10 nm.

Using an ellipsometer which is a device capable of measuring optical properties such as thickness and refractive index of the metal film by using the polarization characteristics of light for the manufactured low-temperature deposition film (Mo metal film), the thickness of the metal film deposited per cycle was calculated by dividing the measured thickness of the metal film by the number of cycles, and the result was 10 nm. Then, sheet resistance was measured using the four-probe measurement method, and the resistivity value was calculated by using the measured thickness.

### Example 7

An ALD deposition process was performed using 5 N HI as a low-temperature deposition material, a TiCl₄ precursor as a precursor compound, and NH₃ using a nitride film reducing agent.

First, the prepared precursor compound was placed in a separate canister and heated to 30° C. Then, the TiCl₄ precursor was injected into the deposition chamber with 100 sccm of Ar carrier for 3 seconds, and then argon gas was supplied at 3000 sccm for 5 seconds to perform argon purging. Next, the prepared low-temperature deposition material was placed in the canister and supplied to the chamber at a flow rate of 1000 sccm for 5 seconds using a mass flow controller (MFC) at room temperature. Then, argon gas was supplied at 3000 sccm for 10 seconds to perform argon purging. At this time, the pressure inside the reaction chamber was controlled to 2.0 Torr. Then, 1000 sccm of NH₃ was supplied for 5 seconds to form a nitride thin film through a reduction reaction, followed by argon purging.

This process was repeated while maintaining the deposition temperature at 500° C. to form a self-limiting atomic layer metal nitride film with a thickness of 10 nm.

### Example 8

An ALD deposition process was performed using 5 N HI as a low-temperature deposition material, an NbF₅ precursor as a precursor compound, and NH₃ using a nitride film reducing agent.

First, the prepared precursor compound was placed in a separate canister and heated to 50° C. Then, the NbF₅ precursor was injected into the deposition chamber with 100 sccm of Ar carrier for 3 seconds, and then argon gas was supplied at 1000 sccm for 6 seconds to perform argon purging. Next, the prepared low-temperature deposition material was placed in the canister and supplied to the chamber at a flow rate of 1000 sccm for 5 seconds using a mass flow controller (MFC) at room temperature. Then, argon gas was supplied at 1000 sccm for 10 seconds to perform argon purging. At this time, the pressure inside the reaction chamber was controlled to 2.0 Torr. Then, 1000 sccm of NH₃ was supplied for 5 seconds to form a nitride thin film through a reduction reaction, followed by argon purging.

This process was repeated while maintaining the deposition temperature at 450° C. to form a self-limiting atomic layer metal nitride film with a thickness of 10 nm.

### Example 9

An ALD deposition process was performed using 3 N tertiary-butyl iodide as a low-temperature deposition material, an MoO₂Cl₂ precursor using a precursor compound, and NH₃ using a nitride film reducing agent.

First, the prepared precursor compound was placed in a separate canister and heated to 120° C. Then, the MoO₂Cl₂ precursor was injected into the deposition chamber with 200 sccm of Ar carrier for 5 seconds, and then argon gas was supplied at 1000 sccm for 5 seconds to perform argon purging. Next, the prepared low-temperature deposition material was placed in the canister and supplied to the chamber at a flow rate of 1000 sccm for 5 seconds using a mass flow controller (MFC) at room temperature. Then, argon gas was supplied at 1000 sccm for 10 seconds to perform argon purging. At this time, the pressure inside the reaction chamber was controlled at 3.0 Torr. Then, 1000 sccm of NH₃ was supplied for 5 seconds to form a nitride thin film through a reduction reaction, followed by argon purging.

This process was repeated while maintaining the deposition temperature at 400° C. to form a self-limiting atomic layer metal nitride film with a thickness of 10 nm.

### COMPARATIVE EXAMPLES

### Comparative Example 1

An ALD deposition process was performed using NH₃ as a thin film-forming material and a BTBMMo precursor represented by the chemical formula below as a precursor compound.

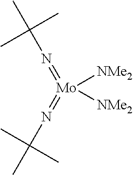

First, the prepared precursor compound was placed in a separate canister and supplied to a separate vaporizer heated to 150° C. at a flow rate of 0.1 g/min using a liquid mass flow controller (LMFC) at room temperature. Then, the BTBMMo precursor vaporized in a vapor phase in the vaporizer was injected into the deposition chamber for 3 seconds, and then argon gas was supplied at 5000 sccm for 10 seconds to perform argon purging. At this time, the pressure inside the reaction chamber was controlled to 2.5 Torr.

Next, the prepared NH₃ as a thin film-forming material was supplied to the chamber at a flow rate of 1000 sccm. Then, the thin film-forming material vaporized in a vapor phase in the vaporizer was injected into the substrate-loaded deposition chamber for 2 seconds to perform a reduction reaction, and then argon gas was supplied at 5000 sccm for 10 seconds to perform argon purging. At this time, the pressure inside the reaction chamber was controlled to 2.5 Torr. This process was repeated 200 to 400 times while maintaining the deposition temperature at 350° C. to form a self-limiting atomic layer thin film with a thickness of 10 nm.

Using an ellipsometer which is a device capable of measuring optical properties such as thickness and refractive index of the thin film by using the polarization characteristics of light for the manufactured thin film (MoN nitride film), the thickness of the thin film deposited per cycle was calculated by dividing the measured thickness of the thin film by the number of cycles, and the result was 10 nm. Thin film component analysis was performed using AES and SIMS analysis. Then, sheet resistance was measured using the four-probe measurement method, and the resistivity value was calculated by using the measured thickness.

### Comparative Example 2

An ALD deposition process was performed using NH₃ as a reactive gas and a BTBTBMo precursor represented by the chemical formula below.

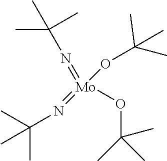

First, the prepared precursor compound was placed in a separate canister and supplied to a separate vaporizer heated to 150° C. at a flow rate of 0.1 g/min using a liquid mass flow controller (LMFC) at room temperature. Then, the BTBTBMo precursor vaporized in a vapor phase in the vaporizer was injected into the deposition chamber for 3 seconds, and then argon gas was supplied at 5000 sccm for 10 seconds to perform argon purging. At this time, the pressure inside the reaction chamber was controlled to 2.5 Torr.

Next, the prepared NH₃ as a reactive gas was supplied to the chamber at a flow rate of 1000 sccm. Then, the reactive gas vaporized in a vapor phase in the vaporizer was injected into the substrate-loaded deposition chamber for 2 seconds to perform a reduction reaction, and then argon gas was supplied at 5000 sccm for 10 seconds to perform argon purging. At this time, the pressure inside the reaction chamber was controlled to 2.5 Torr. This process was repeated 200 to 400 times while maintaining the deposition temperature at 350° C. to form a self-limiting atomic layer thin film with a thickness of 10 nm.

Using an ellipsometer which is a device capable of measuring optical properties such as thickness and refractive index of the thin film by using the polarization characteristics of light for the manufactured thin film (MoN nitride film), the thickness of the thin film deposited per cycle was calculated by dividing the measured thickness of the thin film by the number of cycles, and the result was 10 nm. Thin film component analysis was performed using AES and SIMS analysis. Then, sheet resistance was measured using the four-probe measurement method, and the resistivity value was calculated by using the measured thickness.

### Comparative Example 3

An ALD deposition process was performed using NH₃ as a reactive gas and an Mo(CO)₆ precursor represented by the chemical formula below as a precursor compound.

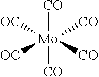

First, the prepared precursor compound was placed in a separate canister and heated to 50° C. Then, the Mo(CO)₆ precursor was injected into the deposition chamber with 50 sccm of Ar carrier for 3 seconds, and then argon gas was supplied at 5000 sccm for 10 seconds to perform argon purging. At this time, the pressure inside the reaction chamber was controlled to 2.5 Torr.

Next, the prepared NH₃ as a reactive gas was supplied to the chamber at a flow rate of 1000 sccm. Then, the reactive gas vaporized in a vapor phase in the vaporizer was injected into the substrate-loaded deposition chamber for 2 seconds to perform a reduction reaction, and then argon gas was supplied at 5000 sccm for 10 seconds to perform argon purging. At this time, the pressure inside the reaction chamber was controlled to 2.5 Torr. This process was repeated 50 to 200 times while maintaining the deposition temperature at 375° C. to form a self-limiting atomic layer thin film with a thickness of 10 nm.

Using an ellipsometer which is a device capable of measuring optical properties such as thickness and refractive index of the thin film by using the polarization characteristics of light for the manufactured thin film (Mo nitride film), the thickness of the thin film deposited per cycle was calculated by dividing the measured thickness of the thin film by the number of cycles, and the result was 10 nm. Then, sheet resistance was measured using the four-probe measurement method, and the resistivity value was calculated by using the measured thickness. The crystallinity of the Mo thin film was confirmed through XRD analysis.

### Comparative Example 4

An ALD deposition process was performed using NH₃ as a reactive gas and an Mo(tol)₂ precursor represented by the chemical formula below as a precursor compound.

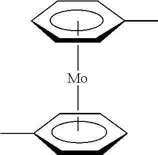

First, the prepared precursor compound was placed in a separate canister and heated to 130° C. Then, the Mo(tol)₂ precursor was injected into the deposition chamber with 50 sccm of Ar carrier for 10 seconds, and then argon gas was supplied at 5000 sccm for 10 seconds to perform argon purging. At this time, the pressure inside the reaction chamber was controlled to 2.5 Torr.

Next, the prepared NH₃ as a reactive gas was supplied to the chamber at a flow rate of 1000 sccm. Then, the reactive gas vaporized in a vapor phase in the vaporizer was injected into the substrate-loaded deposition chamber for 2 seconds to perform a reduction reaction, and then argon gas was supplied at 5000 sccm for 10 seconds to perform argon purging. At this time, the pressure inside the reaction chamber was controlled to 2.5 Torr. The deposition temperatures were maintained at 250 and 300° C., respectively, and this process was repeated 30 to 300 times to form a self-limiting atomic layer thin film with a thickness of 10 nm.

Using an ellipsometer which is a device capable of measuring optical properties such as thickness and refractive index of the thin film by using the polarization characteristics of light for the manufactured thin film (Mo nitride film), the thickness of the thin film deposited per cycle was calculated by dividing the measured thickness of the thin film by the number of cycles, and the result was 10 nm. Then, sheet resistance was measured using the four-probe measurement method, and the resistivity value was calculated by using the measured thickness.

### Comparative Example 5

The bond dissociation energy of the thin film-forming material and metal precursor of the present invention is an important factor in reducing the precursor at low temperatures. The computational simulation program used to calculate bond dissociation energy was Gaussian 16, and the computational simulation method was DFT-D3/B3LYP. The basis set was LanL2DZ for iodine and central metal (e.g., Mo), and 6-31+G(d,p) for other elements.

In addition, the activation energy for the reaction between the Mo(CO)₆, (EtCp)Mo(CO)₂(NO) precursors and H₂ was calculated using the same method. At this time, the transition state method was DFT/TS-Berny and the intrinsic reaction coordinate was 40 pts.

### Comparative Example 6

An ALD deposition process was performed using 99% CH₃I as a thin film-forming material and an MoCl₅ precursor represented by the chemical formula below as a precursor compound.

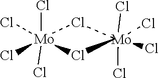

First, the prepared precursor compound was placed in a separate canister and heated to 140° C. Then, the MoCl₅ precursor was injected into the deposition chamber with 100 sccm of Ar carrier for 5 seconds, and then argon gas was supplied at 5000 sccm for 10 seconds to perform argon purging. At this time, the pressure inside the reaction chamber was controlled to 5.0 Torr.

Next, the prepared thin film-forming material was placed in a canister and supplied to the chamber at a flow rate of 1000 sccm using a mass flow controller (MFC) at room temperature. Then, the thin film-forming material vaporized in a vapor phase in the vaporizer was injected into the substrate-loaded deposition chamber for 2 seconds to perform a reduction reaction, and then argon gas was supplied at 5000 sccm for 10 seconds to perform argon purging. At this time, the pressure inside the reaction chamber was controlled at 5.0 Torr. The deposition temperature was maintained at 400 to 600° C., and this process was repeated 30 to 300 times to form a self-limiting atomic layer thin film with a thickness of 10 nm.

### Comparative Example 7

An ALD deposition process was performed using NH₃ as a reactant for nitriding process and a TiCl₄ precursor as a precursor compound.

First, the prepared precursor compound was placed in a separate canister and heated to 50° C. Then, the TiCl₄ precursor was injected into the deposition chamber with 100 sccm of Ar carrier for 3 seconds, and then argon gas was supplied at 3000 sccm for 5 seconds to perform argon purging. At this time, the pressure inside the reaction chamber was controlled to 2.0 Torr.

Next, 1000 sccm of NH₃ as a reactive gas was supplied to the chamber. This process was repeated 50 to 150 times at a deposition temperature of 500 to 550° C. to form a self-limiting atomic layer thin film with a thickness of 10 nm.

### Comparative Example 8

An ALD deposition process was performed using NH₃ as a reactant for nitriding process and an NbF₅ precursor as a precursor compound. The same method was performed except that the low-temperature deposition material of Example 8 was supplied.

### Comparative Example 9

An ALD deposition process was performed using NH₃ as a reactant for nitriding process and an MoO₂Cl₂ precursor as a precursor compound. The same method was performed except that the low-temperature deposition material of Example 9 was supplied.

### Comparative Example 10

An ALD deposition process was performed using H₂ as a reaction material and an MoCl₅ precursor represented by the chemical formula below as a precursor compound.

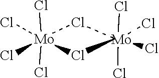

First, the prepared precursor compound was placed in a separate canister and heated to 140° C. Then, the MoCl₅ precursor was injected into the deposition chamber with 100 sccm of Ar carrier for 5 seconds, and then argon gas was supplied at 5000 sccm for 10 seconds to perform argon purging. At this time, the pressure inside the reaction chamber was controlled to 5.0 Torr.

Next, H₂ was used as a reactant, and a reduction reaction was performed by supplying 1000 sccm for 5 seconds, followed by argon purging by supplying 5000 sccm of argon gas for 10 seconds. At this time, the pressure in the reaction chamber was controlled at 5.0 Torr. The deposition temperature was maintained at 400° C.

### Test Examples

For each of the thin films of Examples 1 to 9 and Comparative Examples 1 to 10, the impurity content, the types and contents of elements constituting the material surface, the deposition rate, the crystal structure, and the orientation were analyzed and confirmed in the following manner.
SIMS (Secondary-ion mass spectrometry) C impurities: By sputtering the thin film axially with ion sputtering, the C impurity value was confirmed from the SIMS graph by considering the C impurity content (counts) at a sputtering time of 50 seconds, when surface contamination of a substrate was minimal.
AES (Auger electron spectroscopy): The types and contents of elements constituting the material surface were analyzed by irradiating the material surface with a focused electron beam and measuring the energy of the emitted Auger electrons.
Deposition rate (GPC) measurement: For each of the thin films of Examples 1 to 9 and Comparative Examples 1 to 9, the deposition rate (GPC) was measured in the following manner. Specifically, the deposition rate of thin films having a thickness of 3 to 30 nm was measured using an ellipsometer, and the unit of A/cycle was used.
Grazing-incidence angle (incident angle, θ=3°) X-ray diffractometry: To confirm information such as crystal structure and orientation, diffraction analysis of the surface was performed using Cu-Kα X-ray.

TABLE 1

| | | Precursor | | |
|---|---|---|---|---|
| | | BTBMMo | | |
| | | Comparative | | |
| Target | | Example 1 | Example 1 | Example 2 |
| Thin film-forming material | | NH3 | HI | HI → NH3 |
| Process temperature | | 350° C. | | |
| Deposition rate (Å/cycle) | | 0.7 | 0.8 | 0.3 |
| Resistivity (μΩ · cm) | | −1600 | 1672 | 1667 |
| Mo/N (AES) | | 1.3 | 0.9 | 0.9 |
| C impurity (AES) | | 28 | 0 | 0 |
| O impurity (AES) | | 9 | 18 | 10 |
| Density (g/cm³) | | 6.0 | 6.7 | 6.8 |
| SIMS | C⁻ | 46762 | — | 4054 |
| | CN⁻ | 10996 | — | 1177 |

As shown in Table 1, according to the present invention, when using an HI thin film-forming material alone process or a combined process of an HI thin film-forming material and NH₃ reactive gas, it can be confirmed that the amount of C impurities generated when NH₃ reaction gas is used alone is significantly reduced.

In addition, as shown in Examples 1 and 2, it was confirmed from the AES analysis results that C impurities were reduced to 0% during thin film formation, and according to the SIMS results, the number of detected C ions was confirmed to be reduced by 91% or more.

In addition, since the thin film density increased from 6.0 to 6.8, it can be seen that a very high-quality MoN thin film was formed.

TABLE 2

| | | Precursor | | |
|---|---|---|---|---|
| | | BTBTBMo | | |
| | | Comparative | | |
| Target | | Example 2 | Example 3 | Example 4 |
| Thin film-forming material | | NH3 | HI | HI → NH3 |
| Process temperature | | 350° C. | | |
| Deposition rate (Å/cycle) | | −0.55 | 0.3 | 0.5 |
| Resistivity (μΩ · cm) | | −2500 | −1800 | −1800 |
| Mo/N (AES) | | 0.7 | 1.0 | 0.9 |
| C impurity (AES) | | 0 | 0 | 0 |
| O impurity (AES) | | 21 | 18 | 12 |
| Density (g/cm³) | | 6.83 | 6.80 | 6.90 |
| SIMS | C⁻ | 11774 | 2934 | 4534 |
| | CN⁻ | 2817 | 708 | 1055 |

As shown in Table 2, according to the present invention, when using an HI thin film-forming material alone process or a combined process of an HI thin film-forming material and NH₃ reactive gas, compared with the case of using NH₃ reaction gas alone, the resistivity of the formed thin film was significantly reduced. The impurities of C were also shown to be most effectively reduced when using HI thin film-forming material alone in the order of Comparative Example 2>Example 4>Example 3.

TABLE 3

Precursor
Mo(CO)₆

| | Comparative | |
|---|---|---|
| Target | Example 3 | Example 5 |
| Thin film-forming material | NH3 | HI |

| | |
|---|---|
| Process temperature (° C.) | 375 |

| | | |
|---|---|---|
| Deposition rate (Å/cycle) | −0.6 | −1.8 |
| Resistivity (μΩ · cm) | 415 | 56 |

As shown in Table 3, according to the present invention, when the HI thin film forming material was used, compared with the case of using NH₃ reaction gas alone, the resistivity of the formed thin film was significantly reduced, and the deposition rate increased more than threefold.

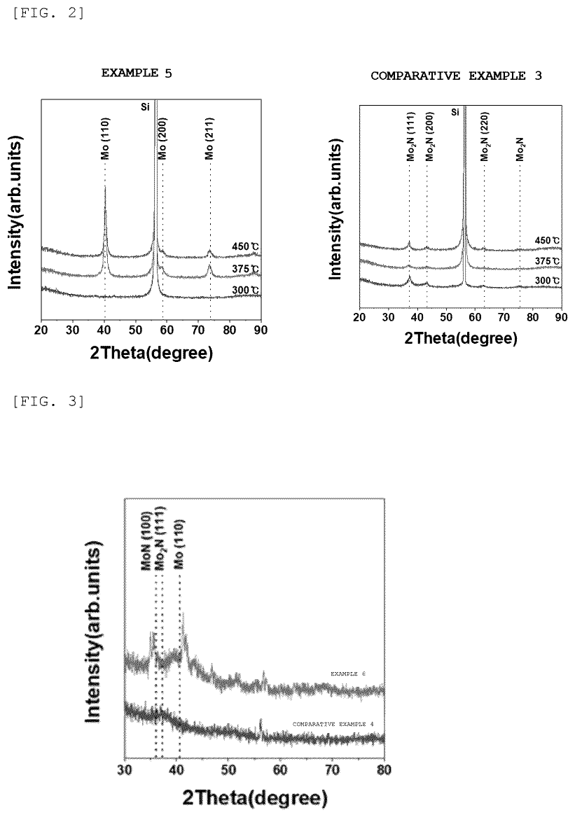

In addition, XRD analysis was performed according to process temperature, and the results are shown in FIG. 2 below. FIG. 2 is a graph showing the XRD analysis results according to process temperature between Example 5 of the present invention and Comparative Example 3.

As shown in FIG. 2 below, Example 5 shows that a pure Mo metal thin film was formed.

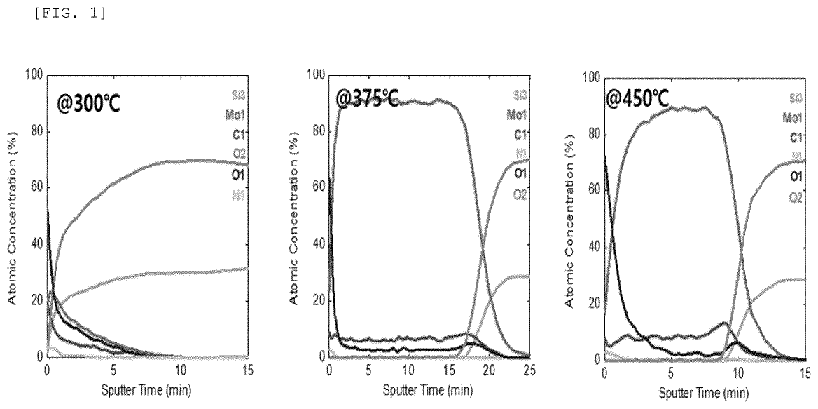

In addition, the temperature-dependent AES analysis results of Example 5 are shown in FIG. 1 below.

FIG. 1 includes graphs showing the AES analysis results for Example 5 according to the present invention at different temperatures. As shown in FIG. 1 below, the changes in the types and contents of the constituent elements according to the process temperature were confirmed.

TABLE 4

| | Precursor | |
|---|---|---|
| | Mo(tol)₂ | |
| | Comparative | |
| Target | Example 4 | Example 6 |

| | | | |
|---|---|---|---|
| Thin film-forming material | NH3 | HI | HI |
| Process temperature (° C.) | 250 | 250 | 300 |
| Deposition rate (Å/cycle) | 0.37 | 0.83 | −2.5 |
| Resistivity (μΩ · cm) | 22800 | 10900 | 800 |

As shown in Table 4, according to the present invention, when the HI thin film forming material was used, compared with the case of using only the NH₃ reaction gas, the resistivity of the formed thin film was significantly reduced, and the deposition rate increased more than twofold.

In addition, XRD analysis was performed and the results are shown in FIG. 3. FIG. 3 is an XRD analysis graph between Example 6 of the present invention and Comparative Example 4.

As shown in FIG. 3 below, it can be seen that a partially pure Mo metal thin film was formed in Example 6.

TABLE 5

| | Precursor | | | | |
|---|---|---|---|---|---|
| | Mo(Cl) [symbol] | | | | |
| | | | | Comparative | Comparative |
| Target | Example 7 | | | Example 6 | Example 10 |
| Thin film-forming material | HI | HI | CH3I | CH3I | H [symbol] |
| Bond dissociation energy | 314.16 | 314.16 | 235.38 | 250.15 | 467.7 |
| (KJ/mol) | | | | | |
| Process temperature (° C.) | 400 | 500 | 500 | 500 | 400 |
| Deposition rate (Å/cycle) | 1.7 | 1.7 | 1.7 | 1.8 | 0 |
| Resistivity (μΩ · cm) | 52 | 13 | 14 | 151 | — |
| Thin film types | Mo | Mo | Mo | Mo + C | — |

[symbol]

indicates data missing or illegible when filed

As shown in Table 5, it can be seen that when the HI thin film forming material was used according to the present invention, the Mo metal thin film with low resistivity was formed even at a low temperature of 400° C. In addition, it can be seen that even in the case of iodine bonded to carbon, when I-1 having a low bond dissociation energy was used, an Mo thin film was formed without carbon impurities. However, in the case of CH₃I having a strong carbon-iodine bond of 250 kJ/mol, not only did the resistivity increase more than tenfold, but carbon impurities were also found to be present in the thin film. These results are obtained because the increase in resistivity is caused by carbon, which acts as an impurity inside the thin film.

The residual mechanism of thin film impurities is that when the bond dissociation energy between carbon and iodine is high, the iodine bond does not dissociate, or the dissociated carbon molecules strongly bond to the substrate surface and are not desorbed.

In addition, in Comparative Example 10 using H₂, which has a high bond dissociation energy, an Mo thin film was not formed at the low temperature of 400° C.

In addition, in Example 8, the results of calculating the bond dissociation energy of carbon- or hydrogen-containing compounds bonded with iodine are shown in Table 6 below.

TABLE 6

| | | BDE(C-I) |
|---|---|---|
| | Structure | (kJ/mol) |
| I-1 | 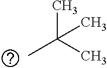 | 236.38 |
| I-2 | 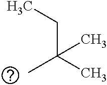 | 239.29 |
| I-3 | 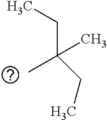 | 241.02 |
| I-4 | 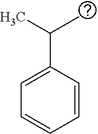 | 194.21 |
| I-5 | 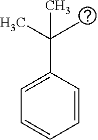 | 186.78 |
| I-6 | HI | 314.18 |
| I-7 | 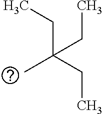 | 241.36 |
| I-8 | 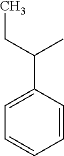 | 197.09 |
| I-9 | ICl | 150.26 |
| I-10 | IBr | 134.59 |
| I-11 | ICl₃ | 68.23 |

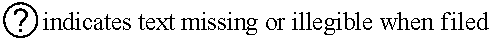

In addition, CH₃I used in Comparative Example 6 had a bond dissociation energy of 250.15 kJ/mol.

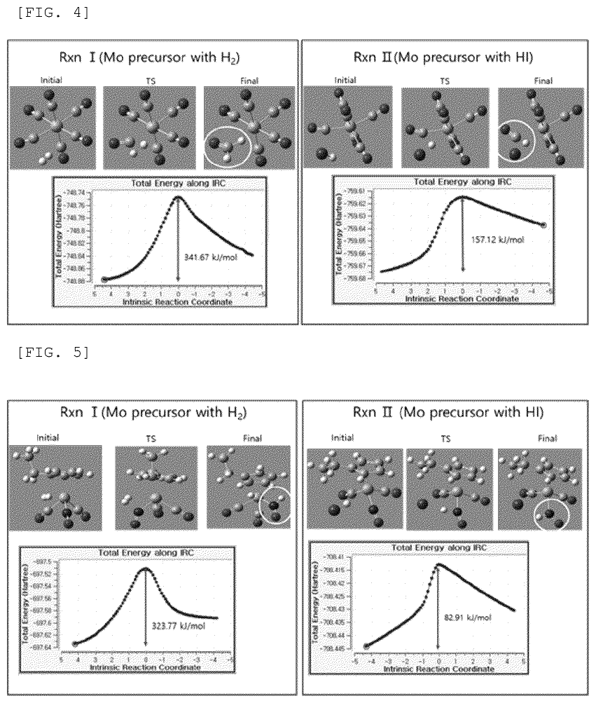

In Example 8 and Comparative Example 5, the reaction activation energy required to reduce the CO ligand of the Mo(CO)₆ precursor and the NO ligand of the (EtCp)Mo(CO)₂(NO) precursor was compared for H₂ and HI, and the results are shown in FIGS. 4 and 5 below.

As shown in FIGS. 4 and 5 below, in the Mo(CO)₆ precursor, the energy required to reduce the CO ligand using H₂ was 341.67 kJ/mol, whereas when HI was used, it was confirmed to be a much lower activation energy of 157.12 kJ/mol. This result demonstrates that reduction can be achieved at even lower process temperatures without C and O impurities.

In addition, in the (EtCp)Mo(CO)₂(NO) precursor, the energy required to reduce the NO ligand using H₂ was 323.77 kJ/mol, whereas when HI was used, it was confirmed to be a much lower activation energy of 82.91 kJ/mol. This result demonstrates that reduction can be achieved at even lower process temperatures without N and O impurities.

The bond dissociation energy of Mo precursors suitable for low-temperature processes is shown in Table 7 below.

TABLE 7

| | | | | Reduction reaction |
|---|---|---|---|---|
| | Chemical | | Mo ligand | at process temperatures |
| [symbol] | Formula | Ligand | Binding energy | below 400° C. |
| 1 | [symbol] | Oxo | [symbol] Kj/mol | X |
| | | Chlorate | [symbol] Kj/mol | X |
| 2 | [symbol] | chloride | [symbol] Kj/mol | ◯ |
| 3 | 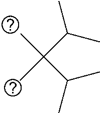 | Imide Amide | [symbol] Kj/mol [symbol] Kj/mol | X ◯ |
| 4 | 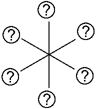 | Carbonyl | [symbol] Kj/mol | ◯ |
| 5 | 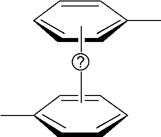 | Toluene | 283.7 Kj/mol | ◯ |
| 6 | 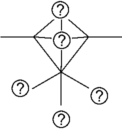 | [symbol] [symbol] [symbol] | [symbol] Kj/mol [symbol] Kj/mol [symbol] Kj/mol | X ◯ ◯ |
| 7 | 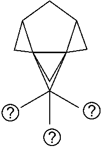 | [symbol] [symbol] | [symbol] Kj/mol [symbol] Kj/mol | X ◯ |

[symbol]

indicates data missing or illegible when filed

As shown in Table 7, it is confirmed that when the bond dissociation energy between Mo and the ligands bonded thereto is 350 kJ/mol or less, reduction occurs at 400° C. or lower.

Table 8 below shows the resistivity results according to bond dissociation energy among the inventive materials used to reduce the reaction activation energy between TiCl₁₄ and NH₃ reaction gas during TiN thin film formation.

TABLE 8

| | | | Bond | | Average | Change in resisivitiy |
|---|---|---|---|---|---|---|
| | TiN process | Chemical | dissociation | GPC | resistivity | compared to when |
| # | @ 550° C. | Formula | energy | (Å/cycle) | (μΩ · cm) | catalyst is used |
| 1 | No catalyst | — | — | 0.38 | 200 | |
| | used | | | | | |
| 2 | I-7 | 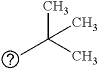 | 236.38 | 0.57 | 113 | Improved resistivity |
| 3 | I-8 | 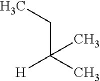 | 238.29 | 0.58 | 117 | Improved resistivity |
| 4 | I-12 | HI | 314.18 | 0.72 | 112 | Improved |
| | | | | | | resistivity |
| 5 | I-10 | 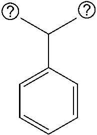 | 194.23 | 0.65 | 110 | Improved resistivity |
| 6 | I-3 | 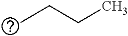 | 250.8 | 0.6 | 574 | Resistivity degradation |
| 7 | I-5 | 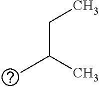 | 244.65 | 0.53 | 392 | Resistivity degradation |
| 8 | I-1 | 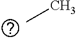 | 250.15 | 0.33 | 752 | Resistivity degradation |

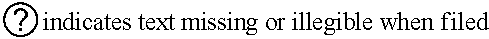

A shown in Table 8, except for CH₃I₂, which has no carbon-iodine bond, it was confirmed that in the case of iodine bonded to carbon, only the materials having a bond dissociation energy of 242 kJ/mol or less not only improved the deposition rate but also exhibited an effect of improving resistivity.

In particular, it was confirmed that as the bond dissociation energy between carbon and iodine increased, the extent of resistivity deterioration also increased.

TABLE 9

| | Whether [symbol] -temperature | Deposition | | | | |
|---|---|---|---|---|---|---|
| | deposition material | rate | Resistivity | Impurities (cps) | | |
| Thin films | was used | (A/cycle) | (μΩ · cm) | [symbol] | [symbol] | [symbol] |
| TiN | ◯ | 0.8 | 40 | | 358 | |
| | X | 0.3 | 82 | | 3,506 | |
| NbN | ◯ | 0.7 | 2119 | — | — | 7,520 |
| | X | 0.4 | 3028 | — | — | 116,900 |
| MoN | ◯ | 0.8 | 800 | 183 | 1,231 | — |
| | X | 0.6 | 1500 | 240 | 1,574 | — |

[symbol]

indicates data missing or illegible when filed

As shown in Table 9, in each low-temperature process, it was confirmed that the use of a low-temperature deposition material in forming a metal nitride film not only improved the deposition rate and resistivity, but also reduced the impurities remaining in the thin film due to insufficient reduction of the precursor ligands in the low-temperature process.

In conclusion, when a predetermined thin film-forming material capable of performing a catalytic reaction or a reduction reaction was used for a precursor compound adsorbed on the surface of a substrate loaded inside a chamber at a relatively low process temperature so that a precursor does not decompose, the film quality of a low-temperature deposition film, such as electrical properties and crystallinity, was improved while preventing the inflow of film impurities caused by ligands such as carbon.

1. A low-temperature deposition material for a wiring metal, a metal having a melting point of 350° C. or less, or a wiring metal diffusion barrier, comprising one or more selected from a compound having a direct bond between hydrogen (H) and iodine, a compound having a direct bond between carbon (C) and iodine, and a compound having a direct bond between a halogen element (F, Cl, Br) and iodine.

2. The low-temperature deposition material according to claim 1, wherein the wiring metal or the metal having a melting point of 350° C. or less is selected from Mo, W, Ru, Cu, Rh, Pb, Cd, Sn, Bi, In, and Ga, and
the wiring metal diffusion barrier is selected from a transition metal nitride film of Ti, Ta, Ni, Mo, Nb, Zr, V, or W, or a combination of two or more metals.

3. The low-temperature deposition material according to claim 1, wherein the compound having a direct bond between hydrogen (H) and iodine has a total bonding energy of 305 to 325 kJ/mol as calculated using a Gaussian 16 program (basis set of DFT-D3/B3LYP (iodine: LanL2DZ, carbon, hydrogen elements: 6-31+G(d·p)).

4. The low-temperature deposition material according to claim 1, wherein the compound having a direct bond between carbon (C) and iodine has a total bonding energy of 165 to 242 kJ/mol as calculated using a Gaussian 16 program (basis set of DFT-D3/B3LYP (iodine: LanL2DZ, carbon, hydrogen elements: 6-31+G(d·p)).

5. The low-temperature deposition material according to claim 1, wherein the compound having a direct bond between a halogen element (F, Cl, Br) and iodine has a total bonding energy of 50 to 160 kJ/mol as calculated using a Gaussian 16 program (basis set of DFT-D3/B3LYP (iodine: LanL2DZ, carbon, hydrogen elements: 6-31+G(d·p)).

6. The low-temperature deposition material according to claim 1, wherein the low-temperature deposition material comprises one or more selected from compounds represented by Chemical Formulas 1-1 to 1-11 below.

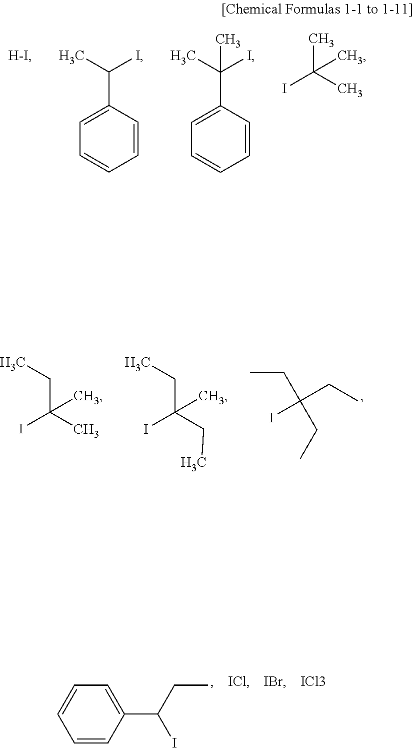

7. A method of forming a low-temperature deposition film, comprising depositing a deposition film using the low-temperature deposition material according to claim 1.

8. The method according to claim 7, wherein the deposition film is a metal film and/or a metal nitride film.

9. The method according to claim 7, comprising forming a deposition film through a reduction reaction while injecting a precursor compound and the low-temperature deposition material into a chamber and adsorbing the precursor compound and the low-temperature deposition material onto a surface of a substrate.

10. The method according to claim 7, characterized by omitting a step of performing a reduction reaction by injecting hydrogen as a reactive gas.

11. The method according to claim 7, comprising a post-processing step of purging an inside of a chamber with a purge gas.

12. The method according to claim 9, wherein the chamber is an ALD chamber, a CVD chamber, a PEALD chamber, or a PECVD chamber.

13. The method according to claim 7, wherein the low-temperature deposition film is a laminated film of one or more metals selected from the group consisting of Mo, W, Ru, Cu, Rh, Pb, Cd, Sn, Bi, In, and Ga.

14. The method according to claim 7, wherein the low-temperature deposition film has a resistivity of 5 μΩ·cm to 1000 μΩ·cm.

15. The method according to claim 9, wherein the precursor compound is a molecule having at least one selected from the group consisting of Mo, W, Ru, Cu, Rh, Pb, Cd, Sn, Bi, In, and Ga as a central metal atom (M) and having one or more ligands selected from C, N, O, H, and X (halogen), and is a compound having a bond dissociation energy of 350 kJ/mol or less between the central metal atom and the ligands to reduce the central metal atom at a low process temperature of 400° C. or lower, as calculated using a Gaussian 16 program (basis set of DFT-D3/B3LYP (central metal, iodine: LanL2DZ, C, N, O, H, X: 6-31+G(d·p)).

16. The method according to claim 9, wherein the substate is heated to 100 to 700° C.

17. A semiconductor substrate comprising the low-temperature deposition film manufactured using the method according to claim 7.

18. A semiconductor device comprising the semiconductor substrate according to claim 17.
